(19) United States
(12) Patent Application Publication
(10) Pub. No.: US 2010/0219157 A1
(43) Pub. Date: Sep. 2, 2010

(54) FILM FORMING APPARATUS AND FILM FORMING METHOD

(75) Inventor: Kenji Matsumoto, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/727,992

(22) Filed: Mar. 19, 2010

Related U.S. Application Data
(63) Continuation of application No. PCT/JP2008/066969, filed on Sep. 19, 2008.

(30) Foreign Application Priority Data
Sep. 21, 2007 (JP) 2007-244623

(51) Int. Cl. B44C 1/22; C23F 1/08; C23C 16/06

(52) U.S. Cl. 216/37; 118/726; 156/345.29; 427/250

(57) ABSTRACT

A film forming apparatus 100 is provided with a processing chamber 2 for accommodating a wafer W; a gas supply section 10 for supplying inside the processing chamber 2 with a gas containing a Cu material gas and an Mn material gas; a shower head 4 for introducing the gas fed from the gas supply section 10 into the processing chamber 2; and a vacuum pump 8 for exhausting inside the processing chamber 2. The gas supply section 10 is provided with a Cu material storing section 21; an Mn material storing section 22; a manifold 40 to which the Cu material and the Mn material are introduced to be mixed; one vaporizer 42 for vaporizing the mixture formed at the manifold 40; and material gas supply piping 54 for introducing into the shower head 4 the material gas formed by vaporization.

This application is a Continuation Application of PCT International Application No. PCT/JP2008/066969 filed on Sep. 19, 2008, which designated the United States.

### FIELD OF THE INVENTION

The present invention relates to a film forming apparatus and method for forming a CuMn film which is a seed layer for an MnSiₓO_{y} self configuring barrier film employed as a diffusion barrier film when Cu lines are formed in trenches or via holes in manufacturing semiconductor devices.

### BACKGROUND OF THE INVENTION

In recent years, techniques have been required that may lower capacitance between interconnects and improve conductivity of lines and electromigration tolerance depending on the need of high-speed, high-integration semiconductor devices with fine wiring patterns. As an example of such techniques, a Cu multilayer interconnection technology gains popularity that employs as a wiring material copper (Cu) with better conductivity than aluminum (Al) or tungsten (W) and excellent in electromigration tolerance and employs a low-k film as an interlayer dielectric film.

Since Cu is extremely prone to be diffused, Cu may be diffused in an insulation film to deteriorate the capability of a device when Cu lines are formed in trenches or via holes. Accordingly, prior to formation of the Cu lines, a diffusion barrier film may be used. As an example of such a diffusion barrier film, an MnSiₓO_{y} self configuring barrier film draws attention (Japanese Patent Application Publication No. 2005-277390).

To form the MnSiₓO_{y} self configuring barrier film, it is needed to deposit a seed layer of a CuMn film prior to forming such film. It is advantageous to use a CVD method in forming the CuMn film with good step coverage. Examples of such techniques have been disclosed in Japanese Patent Application Publication Nos. 1999-200048 and 2007-67107.

In Japanese Patent Application Publication No. 1999-200048, there has been disclosed an example of forming a CuMn film with CVD by supplying a Cu material (Cu precursor) and an Mn material (Mn precursor) in the gaseous phase with the aid of bubbling of H₂ gases.

Further, in Japanese Patent Application Publication No. 2007-67107, there has been disclosed another example of forming a CuMn film, wherein a Cu precursor and an Mn precursor are separately vaporized by a vaporizer or the like, mixed in the gaseous phase, and then supplied into a chamber.

However, the “bubbling method” disclosed in Japanese Patent Application Publication No. 1999-200048 may suffer from a problem with flow rate controllability of materials (precursors), supply reproducibility, decomposition and deterioration of materials due to being maintained at a high temperature, and the like. Further, vapor pressure of the precursors is needed to be comparatively high and the precursors have a limit to a specific option.

In the technique disclosed in either Japanese Patent Application Publication No. 1999-200048 or Japanese Patent Application Publication No. 2007-67107, Cu precursor and Mn precursor are vaporized independently of each other and then mixed in the gaseous state. In a case where the Cu precursor and the Mn precursor are first vaporized and then mixed, it is difficult to uniformly mix them, likely to negatively affect uniformity in film forming. Further, it makes an apparatus complicated to separately vaporize the Cu precursor and the Mn precursor by the vaporizer as disclosed in Japanese Patent Application Publication No. 2007-67107.

### SUMMARY OF THE INVENTION

An object of the present invention is to provide a film forming apparatus and method for forming a CuMn film, having a relatively simple configuration without causing problem with flow rate controllability of materials, supply reproducibility, decomposition and deterioration of materials due to being maintained at high temperature, etc.

Another object of the present invention is to provide a film forming apparatus and method for forming a CuMn film excellent in miscibility of materials.

Still another object of the present invention is to provide a storage medium storing a program for executing the film forming method.

In accordance with a first aspect of the present invention, there is provided a film forming apparatus for forming a CuMn film on a target substrate by supplying gases containing a Cu material gas and an Mn material gas, including: a processing chamber for accommodating the target substrate; a gas supply section for supplying the gases containing the Cu material gas and the Mn material gas into the processing chamber; a gas introduction section for introducing the gases from the gas supply section to the processing chamber; and an exhaust mechanism for exhausting the processing chamber, wherein the gas supply section includes: a Cu material storing section storing a liquid phase Cu material, an Mn material storing section storing a liquid phase Mn material, a vaporizer vaporizing the Cu material and the Mn material, a material supply unit carrying the Cu material from the Cu material storing section and the Mn material from the Mn material storing section to the vaporizer, and a material gas supply piping carrying the Cu material gas and the Mn material gas from the vaporizer to the gas introduction section.

In the first aspect, the Cu material and the Mn material is preferably dissolved in a solvent.

In accordance with a second aspect of the present invention, there is provided a film forming apparatus for forming a CuMn film on a target substrate by supplying gases containing a Cu material gas and an Mn material gas, including: a processing chamber for accommodating the target substrate; a gas supply section for supplying the gases containing the Cu material gas and the Mn material gas into the processing chamber; a gas introduction section for introducing the gases from the gas supply section to the processing chamber; and an exhaust mechanism for exhausting the processing chamber, wherein the gas supply section includes: a Cu material storing section storing a liquid phase Cu material, an Mn material storing section storing a liquid phase Mn material, a mixing section mixing the Cu material as carried with the Mn material as carried, a Cu material supply piping carrying the Cu material from the Cu material storing section to the mixing section, a Mn material supply piping carrying the Mn material from the Mn material storing section to the mixing section, a vaporizer vaporizing a mixture of the Cu material and the Mn material formed in the mixing section, a mixed material supply unit carrying the mixture from the mixed section to the vaporizer, and a material gas supply piping carrying a material gas obtained by vaporizing the mixture in the vaporizer to the gas introduction section.

In the second aspect, preferably, the gas supply section further includes a flow rate control mechanism controlling a flow rate of the Cu material and a flow rate of the Mn material. A ratio in vapor pressure between the Cu material and the Mn material at a same temperature ranging from 40° C. to 200° C. may be within a range between 1:20 and 20:1. In this case, the Cu material may be one of Cu(hfac)TMVS and Cu(hfac)₂ and the Mn material may be one of (MeCp)₂Mn, (EtCp)₂Mn, and (MeCp)Mn(CO)₃. Further, the Cu material and the Mn material may be dissolved in a same solvent. The gas supply section may further include a solvent tank storing the solvent, and a solvent line carrying the solvent from the solvent tank to the mixing section. The solvent may be selected from the group consisting of hexane, cyclohexane, toluene, octane, or pentane, and THF (tetrahydrofuran).

In the first and second aspects, the gas supply section may further include an etching solution tank storing an etching solution for cleaning, and an etching solution supply means carrying the etching solution from the etching solution tank to the vaporizer, wherein the etching solution is vaporized in the vaporizer. The vaporized etching gas may be supplied to the processing chamber, the gas introduction section, and the material gas supply piping to clean them. The vaporized etching gas may be supplied into the processing chamber before the CuMn film is formed to perform reduction cleaning on the substrate prior to the formation of the CuMn film. In this case, the etching solution is preferably an organic acid. The etching solution may be selected from the group consisting of H(hfac), TFAA (trifluoroacetic acid), acetic acid, and formic acid.

In accordance with a third aspect of the present invention, there is provided a film forming method including: mixing a liquid phase Cu material with a liquid phase Mn material; vaporizing by a vaporizer a mixture obtained by mixing the liquid phase Cu material with the liquid phase Mn material; carrying a material gas obtained by said vaporizing over a target substrate in a depressurized processing chamber; and reacting the material gas with the target substrate to form a CuMn film on the target substrate.

In the third aspect, a ratio in vapor pressure between the Cu material and the Mn material at a same temperature ranging from 40° C. to 200° C. is preferably within a range between 1:20 and 20:1. The Cu material may be one of Cu(hfac)TMVS and Cu(hfac)₂ and the Mn material may be one of (MeCp)₂Mn, (EtCp)₂Mn, and (MeCp)Mn(CO)₃.

In the third aspect, the Cu material and the Mn material are preferably dissolved in a same solvent. The solvent may be selected from the group consisting of hexane, cyclohexane, toluene, octane, pentane, and THF (tetrahydrofuran).

In the third aspect, preferably, the film forming method further includes vaporizing an etching solution in the vaporizer without forming the CuMn film during a predetermined period to clean a member including the processing chamber and the line. In this case, the etching solution is preferably an organic acid. The etching solution may be selected from the group consisting of H(hfac), TFAA (trifluoroacetic acid), acetic acid, and formic acid. Preferably, the method further includes vaporizing an etching solution in the vaporizer before forming the CuMn film and supplying it into the processing chamber to perform reduction cleaning on the substrate prior to the formation of the CuMn film.

In accordance with a fourth aspect of the present invention, there is provided a storage medium storing a program that is executed on a computer to control a film forming apparatus, wherein upon execution, the program controls the film forming apparatus through the computer to perform a film forming method, the film forming method including: mixing a liquid phase Cu material with a liquid phase Mn material; vaporizing by a vaporizer a mixture obtained by mixing the liquid phase Cu material with the liquid phase Mn material; carrying a material gas obtained by said vaporizing over a target substrate in a depressurized processing chamber; and reacting the material gas with the target substrate to form a CuMn film on the target substrate.

According to the present invention, since the Cu material and the Mn material are vaporized by the vaporizer to form the CuMn film, there do not occur problems with flow rate controllability of materials, supply reproducibility, decomposition and deterioration of materials due to being maintained at high temperature, etc. Further, since the Cu material and the Mn material are vaporized by the same vaporizer, the apparatus may be configured with simplicity. Further, the Cu material and the Mn material are mixed in the liquid phase and then vaporized, and this leads to good miscibility between the materials.

### BRIEF DESCRIPTION OF THE DRAWINGS

FIG. 1 is a cross sectional view schematically illustrating a film forming apparatus for forming a CuMn film according to an embodiment of the present invention; and

FIG. 2 is a view schematically illustrating a relationship between temperature and vapor pressure with respect to various Cu materials and Mn materials.

### DETAILED DESCRIPTION OF THE EMBODIMENTS

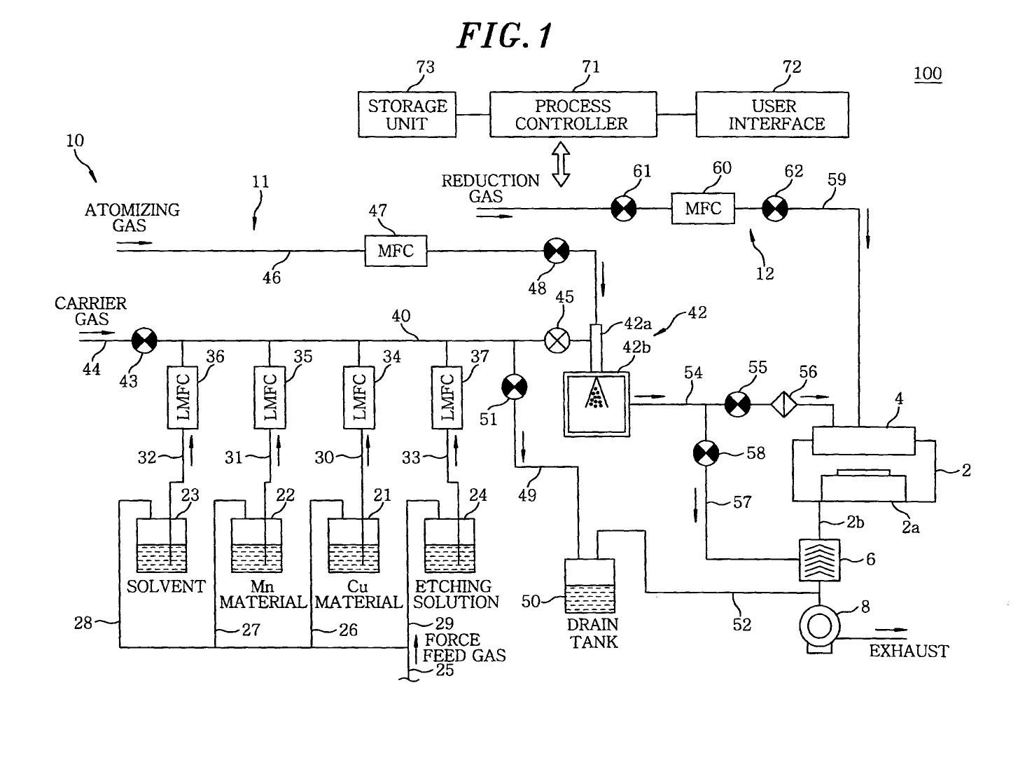

Hereinafter, embodiments of the present invention will be described with reference to accompanying drawings. FIG. 1 is a view schematically illustrating an entire construction of a CuMn film forming apparatus according to an embodiment of the present invention. The CuMn film forming apparatus 100 includes a processing chamber 2, a shower head 4 as a gas introduction section, a gas exhaust trap 6, a vacuum pump 8, and a gas supply section 10.

The processing chamber 2 has a gate valve (not shown) provided at a side wall. A wafer W is loaded into the processing chamber 2 with the gate valve open. The processing chamber 2 also includes therein a mounting table 2a to mount the wafer W thereon. A heater (not shown) is provided in the mounting table 2a to heat the wafer W mounted on the mounting table 2a to a predetermined processing temperature. The processing chamber 2 is connected to a gas exhaust line 2b which is connected to the gas exhaust trap 6 and the vacuum pump 8, and these constitute an exhaust mechanism for the processing chamber 2. The gas exhaust trap 6 traps by-products contained in an exhaust gas to prevent clogging of the line or damage to the vacuum pump. The vacuum pump 8 exhausts the inside of the processing chamber 2 to maintain it at a predetermined vacuum level.

The shower head 4 is provided at a top portion of the processing chamber 2, facing the mounting table 2a, to introduce into the processing chamber 2 a material gas and a reduction gas as processing gases. The shower head 4 introduces the material gas and the reduction gas through different paths and then mixes them-so to speak, “post-mix type”.

The gas supply section 10 supplies processing gases to the shower head 4 and includes a material gas supply section 11 for supplying a material gas and a reduction gas supply section 12 for supplying a reduction gas.

As material storing section, the material gas supply section 11 includes a Cu material storing section 21 for storing a Cu material dissolved in a solvent, an Mn material storing section 22 for storing an Mn material dissolved in a solvent, and a solvent tank 23 for storing a solvent. The Mn material and Cu material dissolved in the respective solvents are in liquid phase. The material gas supply section 11 further includes an etching solution tank 24 for storing an etching solution for cleaning.

Branch lines 26, 27, 28, and 29 as split from a force gas supply line 25 for supplying a force feed gas are connected to the Cu material storing section 21, the Mn material storing section 22, the solvent tank 23, and the etching solution tank 24, respectively, to supply a force feed gas including N₂ gas or an inert gas such as He gas, Ar gas or the like to the tanks, and the pressure generated at that moment discharges liquid phases contained in the tanks.

Cu material supply piping 30, Mn material supply piping 31, solvent supply piping 32, and etching solution supply piping 33, which are connected to liquid phase mass flow controllers (“LMFCs”) 34, 35, 36, and 37, respectively, for controlling flow rate, are immersed into liquid phases contained in the Cu material storing section 21, the Mn material storing section 22, the solvent tank 23, and the etching solution tank 24, respectively. Further, the Cu material supply piping 30, the Mn material supply piping 31, the solvent supply piping 32, and the etching solution supply piping 33 are all connected to a manifold 40. One end of the manifold 40 is connected to a spraying nozzle 42a of a vaporizer 42. The other end of the manifold 40 is connected to a carrier gas line 44 via a valve 43 so that a carrier gas including an inactive gas, such as He gas or Ar gas, or N₂ gas is supplied from the carrier gas line 44 to the manifold 40. The flow rate of the carrier gas is controlled by a mass flow controller (“MFC”) (not shown) provided upstream of the valve 43. A valve 45 is provided near the vaporizer 42 of the manifold 40. The manifold 40 serves as a mixing section for a liquid phase material and is constituted of a thin pipe with an inner diameter of 2.3 mm or less in terms of achieving good mixture and reducing dead space.

A Cu material dissolved in a solvent contained in the Cu material storing section 21 is supplied via the Cu material supply piping 30 to the manifold 40, while it is controlled by the LMFC 34 to have a predetermined flow rate and an Mn material dissolved in a solvent contained in the Mn material storing section 22 is supplied via the Mn material supply piping 31 to the manifold 40, while it is controlled by the LMFC 35 to have a predetermined flow rate. Then, the Cu material and Mn material as supplied are mixed in the manifold 40, and the mixture is carried to the spraying nozzle 42a of the vaporizer 42 by a carrier gas supplied from the carrier gas line 44.

A solvent stored in the solvent tank 23 is also supplied via the solvent supply piping 32 to the manifold 40 while it is controlled by the LMFC 36 to have a predetermined flow rate. The solvent supplied as necessary may be mixed with the mixture of the Cu material and Mn material to adjust the concentration of the mixture. Further, the solvent supplied from the solvent tank 23 may perform pipe cleaning on a liquid phase vaporizing supply system consisting of the manifold 40, the vaporizer 42, a material gas supply piping 54, a filter 56, and valves 45 and 55.

An etching solution stored in the etching solution tank 24 is also supplied via the etching solution supply piping 33 to the manifold 40 while it is controlled by the LMFC 37 to have a predetermined flow rate. Further, the etching solution is supplied through the manifold 40, vaporized by the vaporizer 42, and supplied to the shower head 4 and the processing chamber 2 as necessary at an appropriate time of not performing a film forming process, thereby capable of cleaning them.

The vaporizer 42 includes the spraying nozzle 42a and a main body vessel 42b. Atomizing gas supply piping 46 is connected to an upper end of the spraying nozzle 42a. The atomizing gas supply piping 46 is connected to a mass flow controller (“MFC”) 47 for controlling flow rate and a valve 48 at its downstream side. An atomizing gas including an inert gas, e.g., He gas or Ar gas, or N₂ gas is supplied through the atomizing gas supply piping 46 to the spraying nozzle 42a under the control of its flow rate by the MFC 47 so that the mixture of the Cu material and the Mn material as supplied through the manifold 40 may be sprayed into the main body vessel 42b. The sprayed liquid phase is heated in the main body vessel 42b of the vaporizer 42 to be converted into the gaseous phase.

One end of the material gas supply piping 54 is connected to the main body vessel 42b and the other end of the material gas supply piping 54 is connected to the shower head 4. One end of a bypass line 57 is connected to the material gas supply piping 54 between the main body vessel 42b and the valve 55 and the other end is connected to the gas exhaust trap 6. The opening/closing valve 55 is provided downstream of the point of the material gas supply piping 54 where it is connected to the bypass line 57, and an opening/closing valve 58 is provided on the bypass line 57 adjacent to the material gas supply piping 54. One of the opening/closing valves 55 and 58 is opened to either supply a material gas through the shower head 4 to the processing chamber 2 or allow the material gas to bypass the processing chamber 2 to the gas exhaust line 2b. A filter 56 is disposed downstream of the opening/closing valve 55 of the material gas supply piping 54.

An end of drain piping 49 is connected to the manifold 40 between a point where the manifold 40 and the etching solution supply piping 33 are connected to each other and the valve 45 and the other end of the drain piping 49 is connected to a drain tank 50. An opening/closing valve 51 is disposed over the drain piping 49 adjacent to the manifold 40 and opened to close the valve 45 to guide a liquid phase material from the manifold 40 to the drain tank 50. A drain exhaust line 52 is connected to the drain tank 50. The drain exhaust line 52 is connected to the gas exhaust line 2b of the processing chamber 2 between the gas exhaust trap 6 and the vacuum pump 8. And, the inside of the drain tank 50 is exhausted by the vacuum pump 8 via the drain exhaust line 52, and thus only the solvent is vaporized and exhausted. The source material itself is left and stored in the drain tank 50.

The reduction gas supply section 12 of the gas supply section 10 includes reduction gas supply piping 59 that supplies, e.g., H₂ gas as a reduction gas and is connected to the shower head 4. A mass flow controller (“MFC”) 60 for controlling flow rate is disposed over the reduction gas supply piping 59. And, opening/closing valves 61 and 62 are disposed before and after the MFC 60, respectively. A reduction gas, e.g., H₂ gas, is supplied via the reduction gas supply piping 59 to the shower head 4 under the control of flow rate by the MFC 60.

The configuration units of the CuMn film forming apparatus 100, e.g., the LMFCs 34 to 37, the MFCs 47 and 60, the valves 43, 45, 48, 51, 55, 58, 61, and 62, and the vacuum pump 8, may be connected to and controlled by a process controller 71 having a microprocessor (computer). The process controller 71 is connected to a user interface 72 and a storage unit 73. The user interface 72 may include a keyboard allowing an operator to enter commands for management of the CuMn film forming apparatus 100 or a display displaying operation statuses of the CuMn film forming apparatus 100. The storage unit 73 may store a control program that may implement various processes executed in the CuMn film forming apparatus 100 under the control of the process controller 71 or a program that may perform process on each configuration unit of the CuMn film forming apparatus 100 following processing conditions, so-called “processing recipe”. The processing recipe is stored in a storage medium (not shown) contained in the storage unit 73. The storage medium may be a fixed one, such as hard disks, or a portable one, such as CDROMs, DVDs, flash memories or the like. Further, the processing recipe may be properly transmitted from other devices via, e.g., a dedicated line.

As necessary, any processing recipe may be called from the storage unit 73 by instruction from the user interface 72 and executed by the process controller 71 to perform a desired process in the CuMn film forming apparatus 100 under the control of the process controller 71.

In the CuMn film forming apparatus 100 as configured above, a wafer W is firstly loaded in the processing chamber 2 and mounted on the mounting table 2a with the gate valve (not shown) opened. Subsequently, the gate valve is closed and the inside of the processing chamber 2 is exhausted by the vacuum pump 8 via the gas exhaust line 2b to be maintained at a predetermined vacuum level. Under this situation, the wafer W on the mounting table 2a is heated to a proper temperature ranging from 100° C. to 350° C. by the heater (not shown) buried in the mounting table 2a. Then, the opening/closing valve 55 is first closed and the opening/closing valve 58 is opened so that a material gas obtained by, as described later, vaporizing a mixture of Cu material and Mn material flow from the material gas supply section 11 into the bypass line 57. And when the supply of material gas is stabilized, the opening/closing valve 58 is closed and the opening/closing valve 55 is opened so that the material gas may be supplied via the shower head 4 to the processing chamber 2. On the other hand, a reduction gas, such as H₂ gas, is supplied from the reduction gas supply section 12 via the shower head 4 to the processing chamber 2. The shower head 4 is of a post-mix type as described above, which means the material gas and the reduction gas are introduced via different paths and then mixed in the processing chamber 2.

The material gas and the reduction gas are supplied over the wafer W heated to and maintained at a predetermined temperature and the reduction gas is reduced to form a CuMn film on the wafer W.

The material gas is generated in the following method. A Cu material dissolved by a solvent contained in the Cu material storing section 21 and an Mn material dissolved by a solvent contained in the Mn material storing section 22 are supplied to the manifold 40, which is a gas mixing section, via the Cu material supply piping 30 and the Mn material supply piping 31, respectively, by force feed of gas, under the control of flow rate by the LMFCs 34 and 35, respectively. In the manifold 40, the Cu material and the Mn material are mixed in the liquid phase to be a mixture. Then, the mixture is guided through the manifold 40 to the spraying nozzle 42a of the vaporizer 42 by carrier gas. Thereafter, the mixture is sprayed from the spraying nozzle 42a into the main body vessel 42b by atomizing gas and then vaporized in the main body vessel 42b, thereby generating a material gas with a desired mixing ratio of Cu material and Mn material.

As necessary, for example, upon requiring adjustment of concentration, an appropriate solvent is supplied from the solvent tank 23 through the solvent supply piping 32 to the manifold 40 at a predetermined flow rate to be mixed with the Cu material and the Mn material.

In this situation, since the Cu material and the Mn material are mixed in the liquid phase, it may be possible to ensure excellent miscibility and generate a material gas with uniform mixing ratio of Cu material and Mn material upon vaporizing the materials by the vaporizer 42.

Further, the liquid phase Cu material and Mn material are vaporized by a single vaporizer and this allows for a comparatively simple configuration of the apparatus.

Since the Cu material and the Mn material are vaporized by one vaporizer, the Cu material and the Mn material is preferably configured to have substantially the same vapor pressure at the same temperature. However, it is not necessary to make the Cu material equal to the Mn material in vapor pressure since a CuMn seed layer of an MnSiₓO_{y} self configuring barrier film is relatively low in Mn content. It has been found that the Cu material and the Mn material may be simultaneously vaporized by a single vaporizer only if the difference in vapor pressure is equal to or not more than about a one-digit number. For example, when a vapor pressure ratio between the Cu material and the Mn material is between 1:20 and 20:1 at a same temperature ranging from 40° C. to 200° C., the Cu material and the Mn material may be simultaneously vaporized by a single vaporizer.

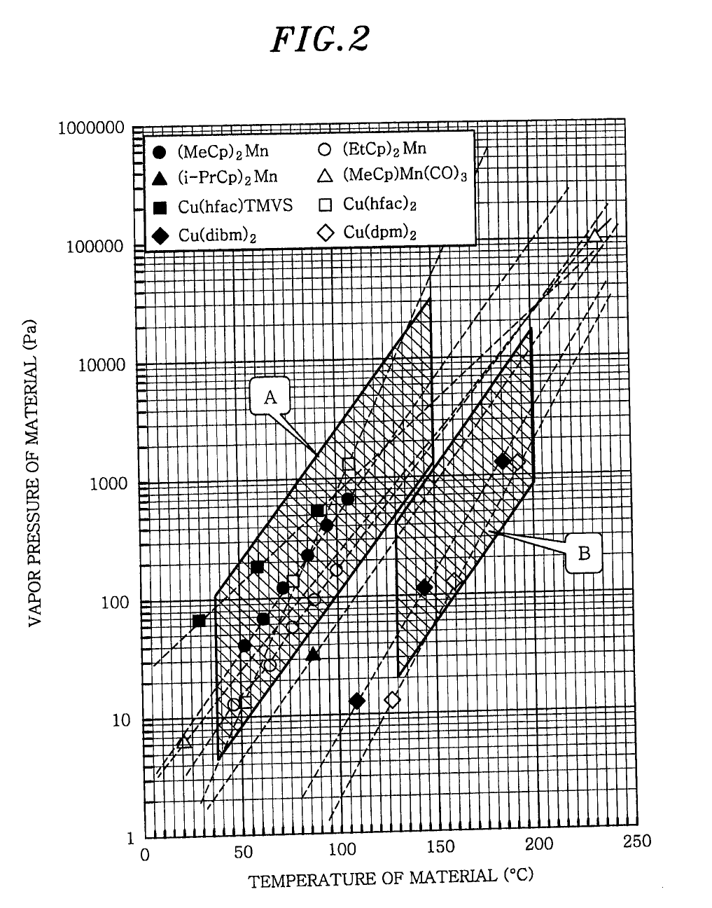

FIG. 2 schematically depicts a relationship between temperature and vapor pressure with respect to various Cu materials and Mn materials. An area A shown by innclined lines in FIG. 2 indicates where the difference in vapor pressure at the same temperature is within a one-digit number range. For example, a vapor pressure ratio between the Cu material and the Mn material is between 1:20 and 20:1 at the same temperature ranging from 40° C. to 150° C. As an example of corresponding to this range, the Cu material may include Cu(hfac)TMVS or Cu(hfac)₂, and the Mn material may include (MeCp)₂Mn, (EtCp)₂Mn, or (MeCp)Mn(CO)₃. Although (MeCp)Mn(CO)₃ is not included in the range indicated by the inclined line A, it may be included in the range by increasing the temperature of the Mn material.

An area B shown by inclined lines B in FIG. 2, as another area, indicates where the difference in vapor pressure at the same temperature is substantially within a one-digit number range. For example, a vapor pressure ratio between the Cu material and the Mn material is between 1:20 and 20:1 at the same temperature ranging from 130° C. to 200° C. As an example of corresponding to this range, the Cu material may include Cu(dibm)₂ or Cu(dpm)₂, and the Mn material may include (i-PrCp)₂Mn.

The combination of these materials allows the materials to be vaporized by the same vaporizer, and may apply to the present invention.

Among these materials, Cu(hfac)₂, Cu(dibm)₂, Cu(dpm)₂, and (MeCp)₂Mn are solid at room temperature and thus are necessary to dissolve in a solvent for use. Although it is not essential to dissolve Cu(hfac)TMVS, (EtCp)₂Mn, (i-PrCp)₂Mn, and (MeCp)Mn(CO)₃, which are liquid phase at room temperature, in a solvent, it is preferable in terms of stable supply that a solvent be added to these materials to lower viscosity in order to facilitate vaporization.

Any solvent not readily reacting with the above materials is preferable and some examples include hydrocarbon, e.g., hexane, cyclohexane, toluene, octane, pentane or the like, and THF (tetrahydrofuran). When a material solution obtained by adding a solvent to the Cu material and Mn material is used, its concentration is preferably in the range of 0.1 mol/L to 0.3 mol/L. Such a material solution may be made by any solvent because it is stable within this range. Further, a vaporization temperature in the vaporizer 42 may range from 40° C. to 130° C. upon using these materials.

As described above, the material gas obtained by vaporizing the Cu material and the Mn material is supplied over the wafer W while the wafer W is simultaneously heated to a temperature between 100° C. and 350° C. to form a CuMn layer. In using the above-mentioned materials, reaction products, which have been separated from Cu atoms and Mn atoms, are relatively stable substances, and thus, swiftly exhausted from the processing chamber 2 without causing a side reaction. Accordingly, it may be possible to supply the Cu material and the Mn material in the same vaporizer and deposit a CuMn film without any disadvantage.

After the formation of the CuMn film, the gate valve of the processing chamber 2 is opened to unload the wafer W placed on the mounting table 2a from the processing chamber 2.

After having formed the CuMn film, dry cleaning is conducted using an etching solution regularly, e.g, after forming the film on a predetermined sheets of wafers, or when necessary. During dry cleaning, an etching solution is supplied from the etching solution tank 24 through the etching solution supply piping 33 to the manifold 40 by gas force feed, vaporized by the vaporizer 42, supplied via the material gas supply piping 54 to the shower head 4, and introduced through the shower head 4 to the inside of the processing chamber 2. By doing so, the vaporizer 42, the material gas supply piping 54, the filter 56, the shower head 4, and the processing chamber 2 are subjected to dry cleaning.

An example of the etching solution may appropriately include an organic acid such as H(hfac), TFAA (trifluoroacetic acid), acetic acid, formic acid, or the like. Accordingly, Cu or Mn attached on the hardware may be vacuum exhausted as a complex, thus capable of being easily removed.

Further, if the vaporized etching solution is supplied over the wafer prior to the formation of the CuMn film which is a seed layer, Cu lines or the like exposed through vias patterned on the wafer may be subjected to reduction cleaning. Accordingly, a plurality of processes may be performed in one processing chamber 2, thus capable of saving costs. Further, the formation of the CuMn film is carried out without the wafer subjected to reduction cleaning being unloaded from the processing chamber 2, thereby preventing deterioration of film quality or occurrence of particles.

An order of forming a CuMn film will now be specifically described.

Cu(hfac)TMVS is employed as a Cu material and (MeCp)₂Mn is employed as an Mn material. These materials are all dissolved in n-hexane to be a material solution. Assuming the temperature of the vaporizer is set to be 60° C., vapor pressures of Cu(hfac)TMVS and (MeCp)₂Mn are 1.4 Torr and 0.5 Torr, respectively. The Mn material has lower vapor pressure and slower deposition speed than the Cu material. However, difference in vapor pressure is within a one-digit number range and there is some CuMn seed layer containing a less amount of Mn, and therefore, CuMn may be deposited without raising any problem by mixing n-hexane with the materials to adjust the concentration of Cu(hfac)TMVS and (MeCp)₂Mn. Further, the use of these materials allows the CuMn film to be formed within a temperature range between 100° C. and 350° C. Since, when using the materials, the reaction products are promptly exhausted from the processing chamber 2 and any side reaction does not easily occur, the materials may be supplied into a single, same vaporizer to form a CuMn film with a good quality.

A number of variations to the present invention may be made without being limited to the above embodiments. For example, although it has been described in the above embodiment that Cu material and Mn material are mixed in the liquid phase and vaporized in the same vaporizer, so that a gasified, mixture of the Cu material and the Mn material is used to form the CuMn film, a material gas obtained by vaporizing the Mn material in the vaporizer may be first supplied to form an Mn film and then a material gas obtained by vaporizing the Cu material in the same vaporizer may be supplied to form a Cu film, thereby completing a Cu/Mn laminated film.

And, although an example has been described where a semiconductor wafer is employed as the substrate, other substrates may also be used without being limited thereto.

What is claimed is:

1. A film forming apparatus for forming a CuMn film on a target substrate by supplying gases containing a Cu material gas and an Mn material gas, comprising:
a processing chamber for accommodating the target substrate;
a gas supply section for supplying the gases containing the Cu material gas and the Mn material gas into the processing chamber;
a gas introduction section for introducing the gases from the gas supply section to the processing chamber; and
an exhaust mechanism for exhausting the processing chamber, wherein
the gas supply section includes:
a Cu material storing section storing a liquid phase Cu material,
an Mn material storing section storing a liquid phase Mn material,
a vaporizer vaporizing the Cu material and the Mn material,
a material supply unit carrying the Cu material from the Cu material storing section and the Mn material from the Mn material storing section to the vaporizer, and
a material gas supply piping carrying the Cu material gas and the Mn material gas from the vaporizer to the gas introduction section.

2. The film forming apparatus of claim 1, wherein the Cu material and the Mn material are dissolved in a solvent.

3. The film forming apparatus of claim 1, wherein the gas supply section further includes:
an etching solution tank storing an etching solution for cleaning, and
an etching solution supply unit carrying the etching solution from the etching solution tank to the vaporizer, wherein the etching solution is vaporized in the vaporizer.

4. The film forming apparatus of claim 3, wherein the vaporized etching gas is supplied to the processing chamber, the gas introduction section, and the material gas supply piping to clean them.

5. The film forming apparatus of claim 3, wherein the vaporized etching gas is supplied into the processing chamber before the CuMn film is formed to perform reduction cleaning on the substrate prior to the formation of the CuMn film.

6. The film forming apparatus of claim 3, wherein the etching solution is an organic acid.

7. The film forming apparatus of claim 6, wherein the etching solution is selected from a group consisting of H(hfac), TFAA (trifluoroacetic acid), acetic acid, and formic acid.

8. A film forming apparatus for forming a CuMn film on a target substrate by supplying gases containing a Cu material gas and an Mn material gas, comprising:
a processing chamber for accommodating the target substrate;
a gas supply section for supplying the gases containing the Cu material gas and the Mn material gas into the processing chamber;
a gas introduction section for introducing the gases from the gas supply section to the processing chamber; and
an exhaust mechanism for exhausting the processing chamber, wherein
the gas supply section includes:
a Cu material storing section storing a liquid phase Cu material,
an Mn material storing section storing a liquid phase Mn material,
a mixing section mixing the Cu material as carried with the Mn material as carried,
a Cu material supply piping carrying the Cu material from the Cu material storing section to the mixing section,
a Mn material supply piping carrying the Mn material from the Mn material storing section to the mixing section,
a vaporizer vaporizing a mixture of the Cu material and the Mn material formed in the mixing section,
a mixed material supply unit carrying the mixture from the mixed section to the vaporizer, and
a material gas supply piping carrying a material gas obtained by vaporizing the mixture in the vaporizer to the gas introduction section.

9. The film forming apparatus of claim 8, wherein the gas supply section further includes:
a flow rate control mechanism controlling a flow rate of the Cu material and a flow rate of the Mn material.

10. The film forming apparatus of claim 8, wherein a ratio in vapor pressure between the Cu material and the Mn material at a same temperature ranging from 40° C. to 200° C. is within a range between 1:20 and 20:1.

11. The film forming apparatus of claim 10, wherein the Cu material is one of Cu(hfac)TMVS and Cu(hfac)₂ and the Mn material is one of (MeCp)₂Mn, (EtCp)₂Mn, and (MeCp)Mn(CO)₃.

12. The film forming apparatus of claim 8, wherein the Cu material and the Mn material are dissolved in a same solvent.

13. The film forming apparatus of claim 12, wherein the gas supply section further includes:
a solvent tank storing the solvent, and
a solvent line carrying the solvent from the solvent tank to the mixing section.

14. The film forming apparatus of claim 12, wherein the solvent is selected from a group consisting of hexane, cyclohexane, toluene, octane, pentane, and THF (tetrahydrofuran).

15. The film forming apparatus of claim 8, wherein the gas supply section further includes:
an etching solution tank storing an etching solution for cleaning, and
an etching solution supply unit carrying the etching solution from the etching solution tank to the vaporizer, wherein the etching solution is vaporized in the vaporizer.

16. The film forming apparatus of claim 15, wherein the vaporized etching gas is supplied to the processing chamber, the gas introduction section, and the material gas supply piping to clean them.

17. The film forming apparatus of claim 15, wherein the vaporized etching gas is supplied into the processing chamber before the CuMn film is formed to perform reduction cleaning on the substrate prior to the formation of the CuMn film.

18. The film forming apparatus of claim 15, wherein the etching solution is an organic acid.

19. The film forming apparatus of claim 18, wherein the etching solution is selected from a group consisting of H(hfac), TFAA (trifluoroacetic acid), acetic acid, and formic acid.

20. A film forming method comprising:
mixing a liquid phase Cu material with a liquid phase Mn material;
vaporizing by a vaporizer a mixture obtained by mixing the liquid phase Cu material with the liquid phase Mn material;
carrying a material gas obtained by said vaporizing over a target substrate in a depressurized processing chamber; and
reacting the material gas with the target substrate to form a CuMn film on the target substrate.

21. The film forming method of claim 20, wherein a ratio in vapor pressure between the Cu material and the Mn material at a same temperature ranging from 40° C. to 200° C. is within a range between 1:20 and 20:1.

22. The film forming method of claim 21, wherein the Cu material is one of Cu(hfac)TMVS and Cu(hfac)₂ and the Mn material is one of (MeCp)₂Mn, (EtCp)₂Mn, and (MeCp)Mn(CO)₃.

23. The film forming method of claim 20, wherein the Cu material and the Mn material are dissolved in a same solvent.

24. The film forming method of claim 23, wherein the solvent is selected from a group consisting of hexane, cyclohexane, toluene, octane, pentane, and THF (tetrahydrofuran).

25. The film forming method of claim 20, further comprising:
vaporizing an etching solution in the vaporizer during a predetermined period when the formation of the CuMn film is not performed to clean a member including the processing chamber and a line.

26. The film forming method of claim 25, wherein the etching solution is an organic acid.

27. The film forming method of claim 26, wherein the etching solution is selected from a group consisting of H(hfac), TFAA (trifluoroacetic acid), acetic acid, and formic acid.

28. The film forming method of claim 20, further comprising:
vaporizing an etching solution in the vaporizer before forming the CuMn film and supplying it into the processing chamber to perform reduction cleaning on the substrate prior to the formation of the CuMn film.

29. A storage medium storing a program that is executed on a computer to control a film forming apparatus, wherein upon execution, the program controls the film forming apparatus through the computer to perform a film forming method, the film forming method comprising:
mixing a liquid phase Cu material with a liquid phase Mn material;
vaporizing by a vaporizer a mixture obtained by mixing the liquid phase Cu material with the liquid phase Mn material;
carrying a material gas obtained by said vaporizing over a target substrate in a depressurized processing chamber; and
reacting the material gas with the target substrate to form a CuMn film on the target substrate.
